(19) United States
(12) Patent Application Publication
(10) Pub. No.: US 2026/0011671 A1
(43) Pub. Date: Jan. 8, 2026

(54) SEMICONDUCTOR DEVICE ASSEMBLIES WITH DISCRETE MEMORY ARRAYS AND CMOS DEVICES CONFIGURED FOR EXTERNAL CONNECTION

(71) Applicant: Micron Technology, Inc., Boise, ID (US)

(72) Inventors: Aaron S. Yip, Los Gatos, CA (US); Kunal R. Parekh, Boise, ID (US); Qui Nguyen, San Jose, CA (US)

(21) Appl. No.: 19/261,646

(22) Filed: Jul. 7, 2025

Related U.S. Application Data
(60) Provisional application No. 63/668,755, filed on Jul. 8, 2024.

(51) Int. Cl. H01L 23/00; H01L 21/48; H01L 21/56; H01L 23/29; H01L 23/31; H01L 23/48; H01L 23/498; H01L 25/18; H10B 80/00; H10D 80/20

(52) U.S. Cl. CPC H01L 24/08; H01L 21/4853; H01L 21/56; H01L 23/291; H01L 23/481; H01L 23/49838; H01L 24/80; H01L 25/18; H10B 80/00; H10D 80/251; H01L 23/3114; H01L 23/3121; H01L 24/94; H01L 24/96; H01L 24/97; H01L 2224/08225; H01L 2224/80895; H01L 2224/80896; H01L 2224/94; H01L 2224/96; H01L 2224/97; H01L 2924/13091

(57) ABSTRACT

A semiconductor device assembly can include a first semiconductor device comprising CMOS circuitry at a first active surface and a second semiconductor device having a footprint smaller than that of the first semiconductor device and including memory array circuitry at a second active surface hybrid-bonded to the first active surface. The assembly can further include a gapfill material directly contacting the first active surface of the first semiconductor device and having an upper surface coplanar with a back surface of the second semiconductor device, and a metallization layer disposed over the second semiconductor device and the gapfill material. The metallization layer can include conductive structures operably coupled to the second semiconductor device through back-side contacts of the second semiconductor device. The assembly can further include a plurality of bond pads disposed at an upper surface of the metallization layer and coupled to the conductive structures of the metallization layer.

### CROSS-REFERENCE TO RELATED APPLICATION(S)

The present application claims priority to U.S. Provisional Patent Application No. 63/668,755, filed Jul. 8, 2024, the disclosure of which is incorporated herein by reference in its entirety.

### TECHNICAL FIELD

The present disclosure generally relates to semiconductor device assemblies, and more particularly relates to semiconductor device assemblies with discrete memory arrays and CMOS devices configured for external connection.

### BACKGROUND

Microelectronic devices generally have a die (i.e., a chip) that includes integrated circuitry with a high density of very small components. Typically, dies include an array of very small bond pads electrically coupled to the integrated circuitry. The bond pads are external electrical contacts through which the supply voltage, signals, etc., are transmitted to and from the integrated circuitry. After dies are formed, they are “packaged” to couple the bond pads to a larger array of electrical terminals that can be more easily coupled to the various power supply lines, signal lines, and ground lines. Conventional processes for packaging dies include electrically coupling the bond pads on the dies to an array of leads, ball pads, or other types of electrical terminals, and encapsulating the dies to protect them from environmental factors (e.g., moisture, particulates, static electricity, and physical impact).

### BRIEF DESCRIPTION OF THE DRAWINGS

FIGS. 1-16 are simplified schematic cross-sectional views illustrating a series of fabrication steps of semiconductor device assemblies in accordance with various embodiments of the present technology.

FIG. 17 is a flow chart illustrating a method of making a semiconductor device assembly in accordance with an embodiment of the present technology.

FIG. 18 is a schematic view showing a system that includes a semiconductor device assembly configured in accordance with an embodiment of the present technology.

### DETAILED DESCRIPTION

Specific details of several embodiments of semiconductor device assemblies, and associated systems and methods are described below. The term “semiconductor device” or “die” generally refers to a solid-state device that includes one or more semiconductor materials. Examples of semiconductor devices include logic devices, memory devices, controllers, or microprocessors (e.g., central processing unit (CPU), graphics processing unit (GPU)), among others. Such semiconductor devices may include integrated circuits or components, data storage elements, processing components, and/or other features manufactured on semiconductor substrates. Further, the term “semiconductor device or die” can refer to a finished device or to an assembly or other structure at various stages of processing before becoming a finished functional device. Depending upon the context in which it is used, the term “substrate” can refer to a wafer-level substrate or to a singulated, die-level substrate. Also, a substrate may include a semiconductor wafer, a package support substrate, an interposer, a semiconductor device or die, or the like. A person having ordinary skill in the relevant art will recognize that suitable steps of the methods described herein can be performed at the wafer level or at the die level.

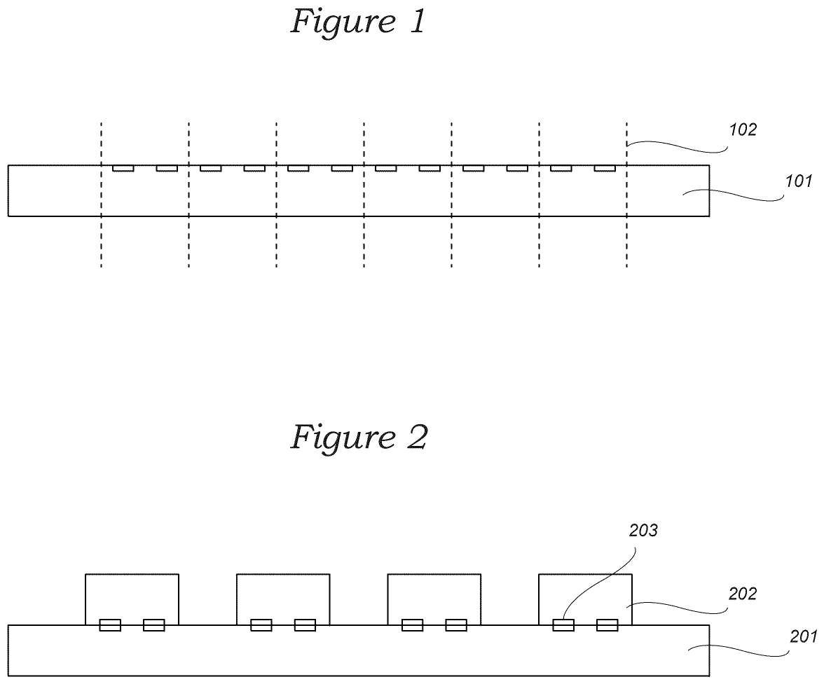

Further, unless the context indicates otherwise, structures disclosed herein can be formed using conventional semiconductor-manufacturing techniques. Materials can be deposited, for example, using chemical vapor deposition (CVD), physical vapor deposition (PVD), atomic layer deposition (ALD), spin coating, plating, and/or other suitable techniques. Similarly, materials can be removed, for example, using plasma etching, wet etching, chemical-mechanical planarization, or other suitable techniques. Some of the techniques may be combined with photolithography processes. A person skilled in the relevant art will also understand that the technology may have additional embodiments, and that the technology may be practiced without several of the details of the embodiments described herein with reference to FIGS. 1 through 18.

Certain semiconductor devices, e.g., a memory device, may include an area with an array of memory cells (which may also be referred to as an array, a memory array, an array region, an array portion, or the like) and another area with peripheral circuitry (which may also be referred to as a periphery, a peripheral region, a peripheral portion, or the like). The array of memory cells may include various types of memory cells, such as dynamic random-access memory (DRAM) cells, phase change memory (PCM) cells, flash memory cells (e.g., NAND cells, NOR cells), among others. The peripheral circuitry can be configured to perform various functions for the semiconductor device, including accessing the memory cells of the array. In some cases, the peripheral region may be referred to as a CMOS region (CMOS, CMOS portion, CMOS area, etc.) in view of complementary-metal-oxide-semiconductor (CMOS) transistors included in the peripheral circuitry. Additionally, or alternatively, the peripheral region may be referred to as a logic region owing to the nature of digital logic functions that the peripheral circuitry performs. As such, the memory device may be regarded to have an array region and a CMOS region (or a peripheral/logic region), among others.

In general, a die size of a memory device may be primarily determined by the area of the array region and the area of the CMOS region. Accordingly, research and development efforts have been focused on reducing both areas—e.g., vertically stacking memory cells (e.g., as in the 3-dimensional (3D) NAND memory technology) to reduce the area of the array region, or CMOS transistor scaling to reduce the area of the CMOS region. Process steps associated with fabricating an array of memory cells, however, may include disparate characteristics than those used for fabricating CMOS circuitry. For example, temperatures of certain CMOS process steps may be higher than those used in memory array process steps (and may be higher than a memory array can withstand without damage). Additionally, or alternatively, defect mechanisms associated with the array of memory cells tend to be different from those associated with the CMOS circuitry.

As such, example embodiments of the present technology involve fabricating the CMOS region and the array region of the memory device as two separate semiconductor devices (or semiconductor dies) to optimize the fabrication processes of the CMOS circuitry and the memory cells independently of each other. Moreover, the two separate dies (e.g., an array die and a CMOS die) may be vertically combined (e.g., stacked to form a pair of semiconductor dies) such that the two (or more) separate dies, in combination, may function as a single device (e.g., one memory device). In some embodiments, front (e.g., active) surfaces of the two semiconductor dies can be arranged to face each other to form the pair such that a distance between the CMOS circuitry and the memory cells may be reduced. Moreover, the front surfaces of the two semiconductor dies may be conjoined to couple the CMOS circuitry with the memory cells of the array through conductive components (e.g., copper (Cu), Cu-containing alloy) at the interface between the array die and the CMOS die. The stack of semiconductor dies (i.e., a semiconductor die stack or a semiconductor device assembly) may provide a smaller footprint and an improved performance (e.g., a reduced delay time owing to the reduced distance between the CMOS circuitry and the memory cells), when compared to a memory device having the CMOS circuitry and the memory cells laterally distributed.

Coupling the assembly of semiconductor dies thus configured to external devices may present a challenge. Embodiments of the present invention provide various approaches to configuring semiconductor device assemblies with combinations of CMOS and memory dies with wire bond pads for external connectivity. In this regard, FIGS. 1-16 are simplified schematic cross-sectional views illustrating a series of fabrication steps of semiconductor device assemblies in accordance with various embodiments of the present technology. Beginning with FIGS. 1 and 2, a wafer 101 (e.g., in wafer-level, panel-level, strip-level, or in some embodiments, pre-singulated) is singulated along streets 102 to provide a plurality of chiplets 202 that are hybrid-bonded to a wafer 201. In accordance with one aspect of the present disclosure, the chiplets 202 can include memory array circuitry (e.g., NAND circuitry, NOR circuitry, DRAM circuitry, MRAM circuitry, FeRAM circuitry, PCM circuitry, etc.). The wafer 201 can include multiple die sites to which corresponding chiplets 202 are bonded, with each die site including CMOS circuitry configured to provide access to and control of the memory array circuitry in the corresponding chiplet 202. For each chiplet 202 hybrid-bonded to the wafer 201, the hybrid-bonding operation involves simultaneously forming dielectric-dielectric (e.g., oxide-oxide, nitride-nitride, oxide-nitride, etc.) bonds between the active surfaces of the chiplet 202 and the wafer 201 and metal-metal (e.g., copper-copper) bonds between interconnects 203 on the active surfaces of the chiplet 202 and the wafer 201.

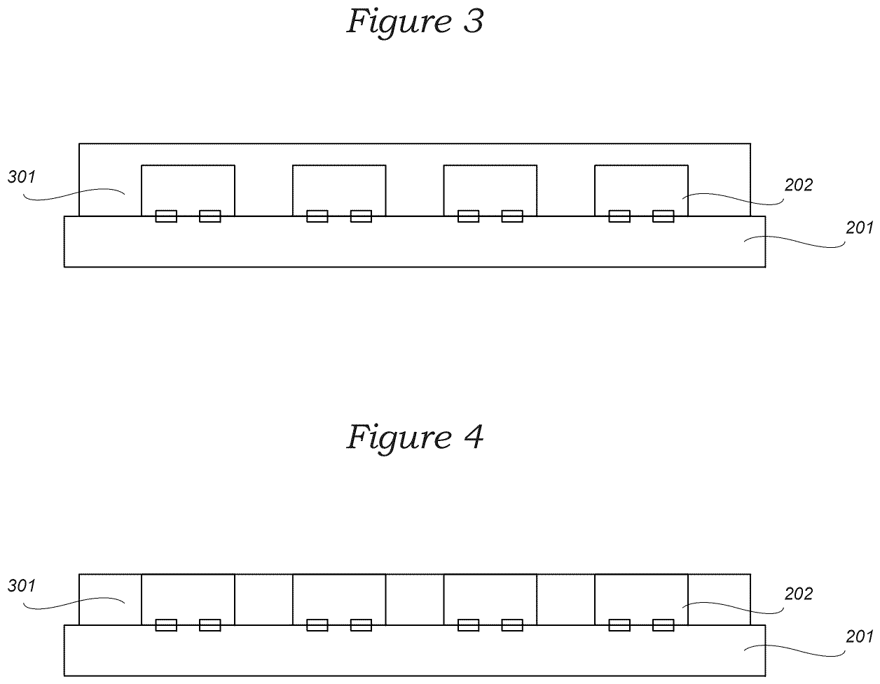

Because the die sites for the CMOS circuitry in the wafer 201 are larger than the chiplets 202, the chiplets 202 are laterally spaced apart from one another following the bonding operation, as shown in FIG. 2. Accordingly, in FIG. 3, a gapfill material 301 is disposed between and over the chiplets 202, directly contacting the surface of the wafer 201. The gapfill material may be an oxide material, or a polymer material, or any other insulating or dielectric material well known to those of skill in the art.

Turning to FIG. 4, further processing of the structure of FIG. 3 is illustrated in accordance with one aspect of the invention in which external wire bond contacts will be formed to communicate with the CMOS circuitry in wafer 201 through the circuitry of the chiplets 202 (e.g., through back-side contacts and through-silicon vias (TSVs) of the chiplets, which are omitted from the illustration for clarity and simplicity). In FIG. 4, the first step of this further processing is illustrated, in which a planarization operation is performed on the gapfill material 301 to expose the back surfaces of the chiplets 202 (and, although not illustrated, the back-side contacts/TSV end surfaces thereon). In some embodiments, the planarization operation may cease when the back surfaces of the chiplets 202 are exposed, while in other embodiments the planarization operation may remove bulk silicon or other semiconductor material from the back surfaces of the chiplets 202 to thin the chiplets 202 to a desired height and/or until a buried TSV is exposed.

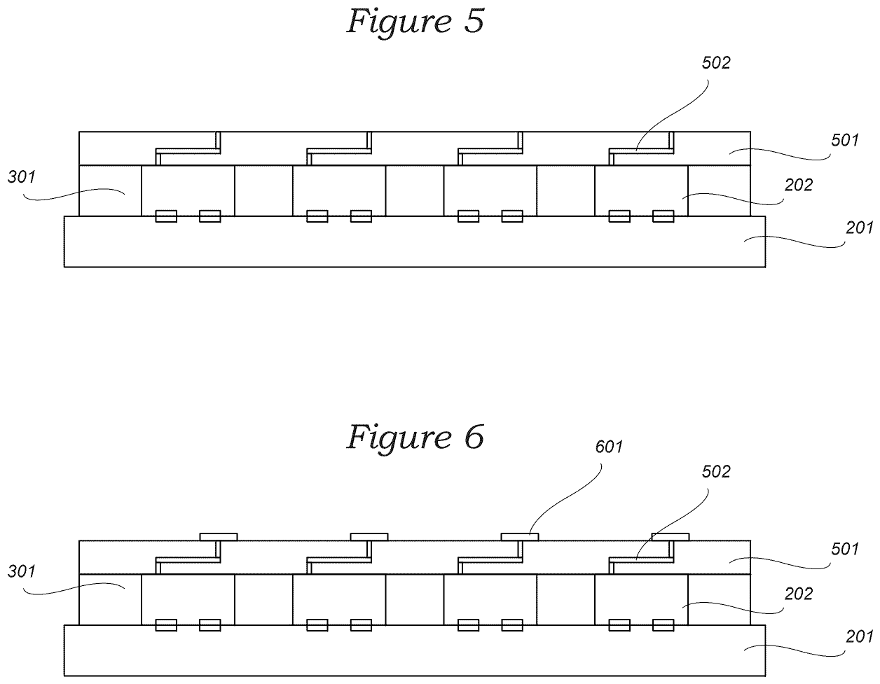

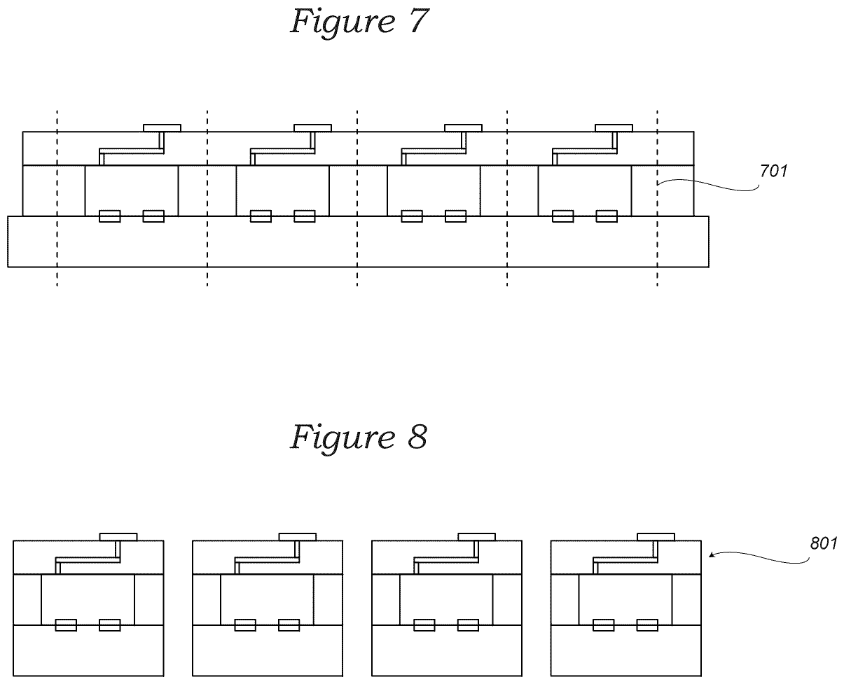

Turning to FIG. 5, one or more metallization layers are formed over the planarized surface, the metallization layers including a dielectric material 501 (e.g., an oxide, a nitride, a polymer, etc.) and conductive structures 502 (e.g., vias, traces, contact pads, etc.). In FIG. 6, wire bond pads 602 are formed over the metallization layer and are operably connected by the conductive structures to back-side contacts/exposed TSVs (not illustrated) of the chiplets. By singulating the structure of FIG. 6 along streets 701, as shown in FIG. 7, individual semiconductor device assemblies 801, as shown in FIG. 8, can be formed.

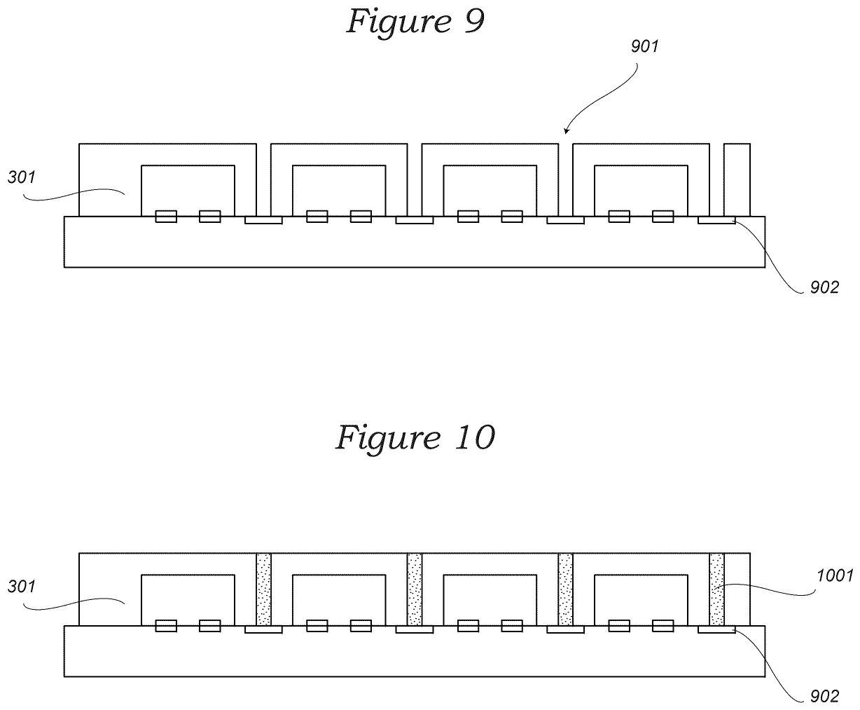

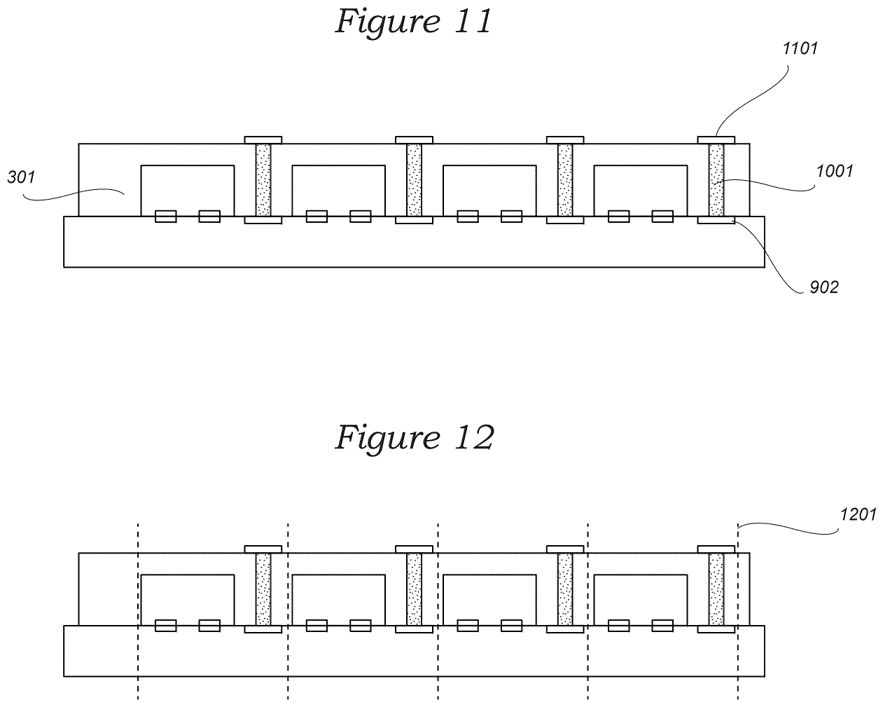

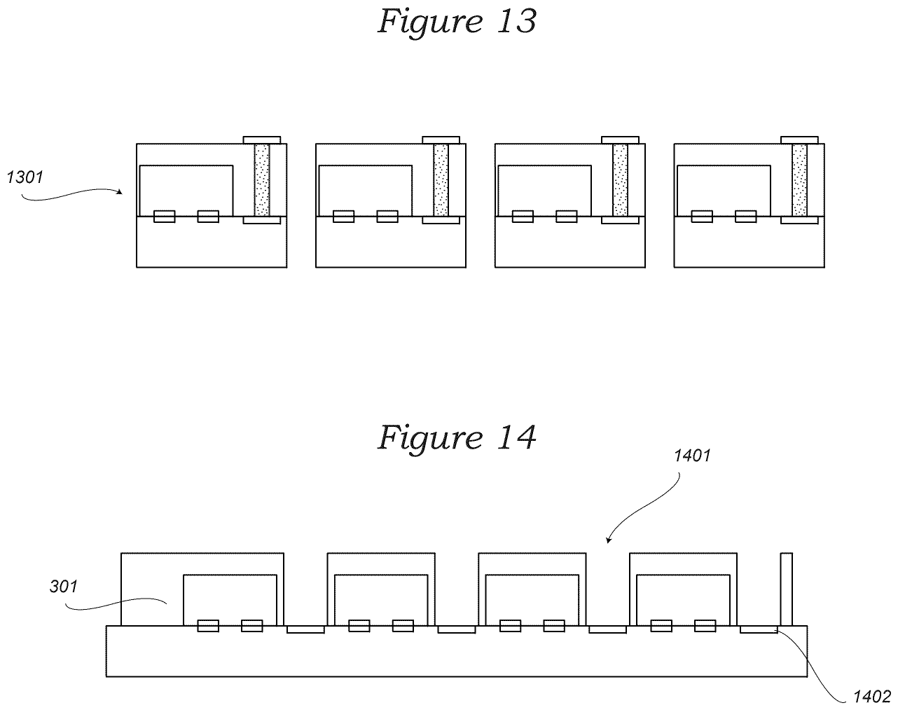

Turning to FIG. 9, further processing of a structure analogous to that of FIG. 3 is illustrated in accordance with another aspect of the invention in which external wire bond contacts will be formed to communicate with the memory array circuitry of the chiplets 202 through circuitry of the wafer 201. In FIG. 9, the first step of this further processing is illustrated, in which openings 901 are formed in the gapfill material 301, the openings 901 vertically aligned with and exposing conductors 902 formed in the wafer. In FIG. 10, through-oxide vias 1001 are formed (e.g., by plating a conductor such as copper) into the openings 901 in electrical contact with the conductors 902 of the wafer. In FIG. 11, wire bond pads 1101 are formed over the through-oxide vias 1001 to provide external electrical contact to the conductors 902 and through those conductors both to CMOS circuitry in the wafer and memory array circuitry in the chiplets. By singulating the structure of FIG. 11 along streets 1201, as shown in FIG. 12, individual semiconductor device assemblies 1301, as shown in FIG. 13, can be formed.

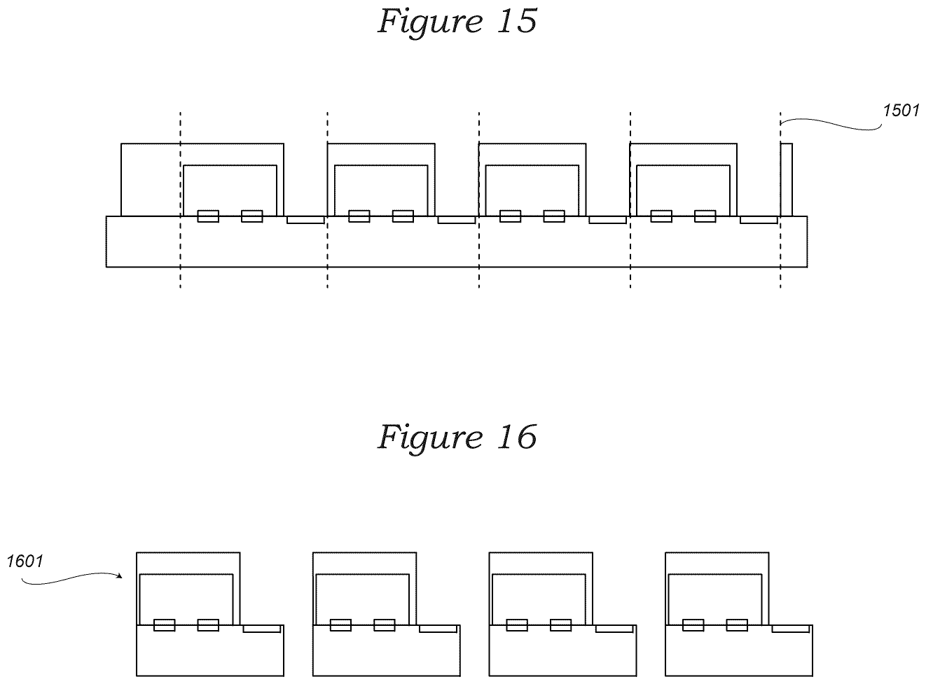

Turning to FIG. 14, further processing of a structure analogous to that of FIG. 3 is illustrated in accordance with another aspect of the invention in which external wire bond contacts will be formed to communicate with the memory array circuitry of the chiplets 202 through circuitry of the wafer 201. In FIG. 14, the first step of this further processing is illustrated, in which openings 1401 are formed in the gapfill material 301, the openings 1401 vertically aligned with and exposing wire bond pads 1402 formed in the wafer. By singulating the structure of FIG. 14 along streets 1501, as shown in FIG. 15, individual semiconductor device assemblies 1601, as shown in FIG. 16, can be formed.

Although in the example embodiment of FIG. 16, individual semiconductor device assemblies 1601 are singulated such that the streets 1501 pass through the openings 1401 (such that the wire bond pads 1402 are formed on a peripheral shelf of the assembly 1601), in other embodiments, the openings 1401 can be formed further from the periphery of the CMOS die singulated from the wafer, such that a wire bond extending to the wire bond pad 1402 passes down through the opening and up over the top of the gapfill material peripheral thereto.

Although in the foregoing example embodiment semiconductor device assemblies have been illustrated and described as including a single chiplet bonded to a die singulated from a CMOS wafer, in other embodiments assemblies can be provided with a stack of chiplets (e.g., pre-stacked and attached to the wafer with a stack-on-wafer (SoW) bonding technique, or stacked in situ with a combination of chip-on-wafer (CoW) and chip-on-chip (CoC) bonding techniques).

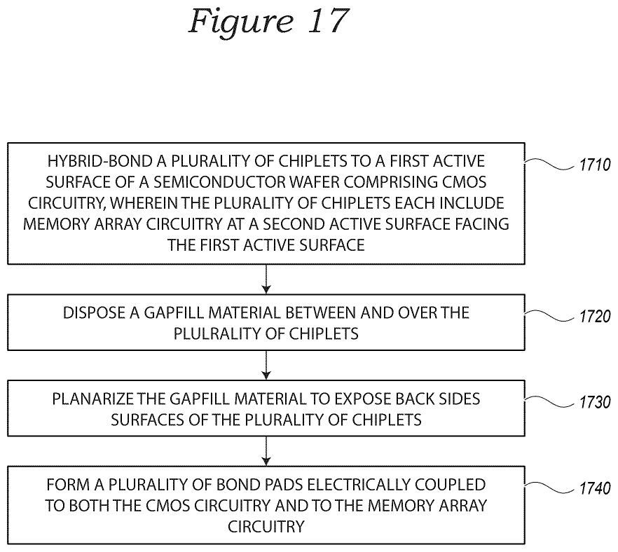

FIG. 17 is a flow chart illustrating a method of making a semiconductor device assembly. The method includes hybrid-bonding a plurality of chiplets to a first active surface of a semiconductor wafer comprising CMOS circuitry, wherein the plurality of chiplets each include memory array circuitry at a second active surface facing the first active surface (box 1710). The method further includes disposing a gapfill material between and over the plurality of chiplets (box 1720). The method further includes planarizing the gapfill material to expose back sides surfaces of the plurality of chiplets (box 1730). The method further includes forming a plurality of bond pads electrically coupled to both the CMOS circuitry and to the memory array circuitry (box 1740). Although not illustrated in FIG. 17, the method can further include forming openings in the gapfill material vertically aligned with the plurality of bond pads. Although not illustrated in FIG. 17, the method can further include forming through-oxide vias by plating a conductor into the openings. Although not illustrated in FIG. 17, the method can further include forming a metallization layer over the plurality of chiplets and the gapfill material, the metallization layer including conductive structures operably coupled to the plurality of chiplets through back-side contacts of the plurality of chiplets.

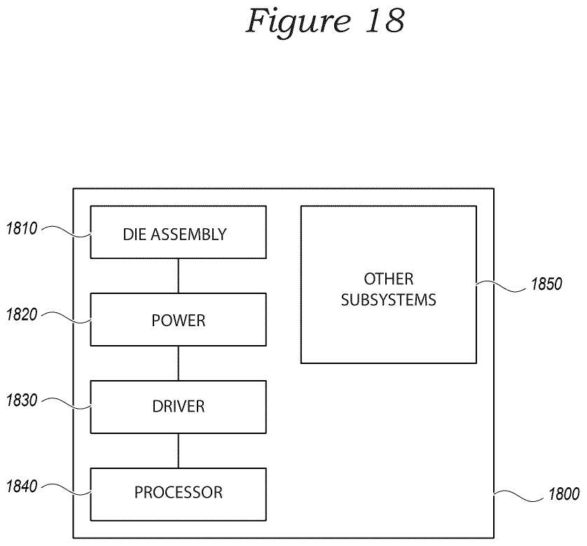

Any one of the semiconductor devices and semiconductor device assemblies described above with reference to FIGS. 1-17 can be incorporated into any of a myriad of larger and/or more complex systems, a representative example of which is system 1800 shown schematically in FIG. 18. The system 1800 can include a semiconductor device assembly (e.g., or a discrete semiconductor device) 1802, a power source 1804, a driver 1806, a processor 1808, and/or other subsystems or components 1810. The semiconductor device assembly 1802 can include features generally similar to those of the semiconductor devices described above with reference to FIGS. 1-17. The resulting system 1800 can perform any of a wide variety of functions, such as memory storage, data processing, and/or other suitable functions. Accordingly, representative systems 1800 can include, without limitation, hand-held devices (e.g., mobile phones, tablets, digital readers, and digital audio players), computers, vehicles, appliances and other products. Components of the system 1800 may be housed in a single unit or distributed over multiple, interconnected units (e.g., through a communications network). The components of the system 1800 can also include remote devices and any of a wide variety of computer readable media.

Specific details of several embodiments of semiconductor devices, and associated systems and methods, are described above. Unless the context indicates otherwise, structures disclosed herein can be formed using conventional semiconductor-manufacturing techniques. Materials can be deposited, for example, using chemical vapor deposition, physical vapor deposition, atomic layer deposition, plating, electroless plating, spin coating, and/or other suitable techniques. Similarly, materials can be removed, for example, using plasma etching, wet etching, chemical-mechanical planarization, or other suitable techniques.

In other embodiments, the term “substrate” can refer to a package-level substrate upon which other semiconductor devices are carried, such as a printed circuit board (PCB), an interposer, or another semiconductor device.

The devices discussed herein, including a memory device, may be formed on a semiconductor substrate or die, such as silicon, germanium, silicon-germanium alloy, gallium arsenide, gallium nitride, etc. In some cases, the substrate is a semiconductor wafer. In other cases, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorous, boron, or arsenic. Doping may be performed during the initial formation or growth of the substrate, by ion-implantation, or by any other doping means.

The functions described herein may be implemented in hardware, software executed by a processor, firmware, or any combination thereof. Other examples and implementations are within the scope of the disclosure and appended claims. Features implementing functions may also be physically located at various positions, including being distributed such that portions of functions are implemented at different physical locations.

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, the terms “vertical,” “lateral,” “upper,” “lower,” “above,” and “below” can refer to relative directions or positions of features in the semiconductor devices in view of the orientation shown in the Figures. For example, “upper” or “uppermost” can refer to a feature positioned closer to the top of a page than another feature. These terms, however, should be construed broadly to include semiconductor devices having other orientations, such as inverted or inclined orientations where top/bottom, over/under, above/below, up/down, and left/right can be interchanged depending on the orientation.

It should be noted that the methods described above describe possible implementations, and that the operations and the steps may be rearranged or otherwise modified and that other implementations are possible. Furthermore, embodiments from two or more of the methods may be combined.

From the foregoing, it will be appreciated that specific embodiments of the invention have been described herein for purposes of illustration, but that various modifications may be made without deviating from the scope of the invention. Rather, in the foregoing description, numerous specific details are discussed to provide a thorough and enabling description for embodiments of the present technology. One skilled in the relevant art, however, will recognize that the disclosure can be practiced without one or more of the specific details. In other instances, well-known structures or operations often associated with memory systems and devices are not shown, or are not described in detail, to avoid obscuring other aspects of the technology. In general, it should be understood that various other devices, systems, and methods in addition to those specific embodiments disclosed herein may be within the scope of the present technology.

What is claimed is:

1. A semiconductor device assembly, comprising:
a first semiconductor device comprising CMOS circuitry at a first active surface;
a second semiconductor device having a second footprint smaller than a first footprint of the first semiconductor device, the second semiconductor device comprising memory array circuitry at a second active surface, the second active surface hybrid-bonded to the first active surface;
a gapfill material directly contacting the first active surface of the first semiconductor device and having an upper surface coplanar with a back surface of the second semiconductor device;
a metallization layer disposed over the second semiconductor device and the gapfill material, the metallization layer including conductive structures operably coupled to the second semiconductor device through back-side contacts of the second semiconductor device; and
a plurality of bond pads disposed at an upper surface of the metallization layer, the plurality of bond pads coupled to the conductive structures of the metallization layer.

2. The semiconductor device assembly of claim 1, wherein the plurality of bond pads is electrically coupled to the first semiconductor device through the second semiconductor device.

3. The semiconductor device assembly of claim 1, wherein first metal contacts at the first active surface are directly bonded to second metal contacts at the second active surface without intermediary solder.

4. The semiconductor device assembly of claim 1, wherein the second semiconductor device comprises through-silicon vias operably coupling the back-side contacts to second metal contacts at the second active surface.

5. The semiconductor device assembly of claim 1, wherein the gapfill material comprises silicon oxide.

6. A semiconductor device assembly, comprising:
a first semiconductor device comprising CMOS circuitry at a first active surface;
a second semiconductor device having a second footprint smaller than a first footprint of the first semiconductor device, the second semiconductor device comprising memory array circuitry at a second active surface, the second active surface hybrid-bonded to the first active surface;
a gapfill material directly contacting the first active surface of the first semiconductor device and having an upper surface coplanar with a back surface of the second semiconductor device;
a plurality of openings in the gapfill material vertically aligned with a corresponding plurality of first conductors at the first active surface; and
a plurality of bond pads vertically aligned with the plurality of openings, the plurality of bond pads electrically coupled to the CMOS circuitry and to the memory array circuitry through the first semiconductor device.

7. The semiconductor device assembly of claim 6, wherein the plurality of bond pads is disposed adjacent the first active surface at corresponding bottoms of the openings.

8. The semiconductor device assembly of claim 6, wherein the plurality of bond pads is disposed over the openings and electrically coupled to the plurality of conductors by a corresponding plurality of through-oxide vias.

9. The semiconductor device assembly of claim 6, wherein first metal contacts at the first active surface are directly bonded to second metal contacts at the second active surface without intermediary solder.

10. The semiconductor device assembly of claim 6, wherein the gapfill material comprises silicon oxide.

11. A method of forming a semiconductor device assembly, the method comprising:
hybrid-bonding a plurality of chiplets to a first active surface of a semiconductor wafer comprising CMOS circuitry, wherein the plurality of chiplets each include memory array circuitry at a second active surface facing the first active surface;
disposing a gapfill material between and over the plurality of chiplets;
planarizing the gapfill material to expose back sides surfaces of the plurality of chiplets;
forming a plurality of bond pads electrically coupled to both the CMOS circuitry and to the memory array circuitry.

12. The method of claim 11, further comprising forming openings in the gapfill material vertically aligned with the plurality of bond pads.

13. The method of claim 12, wherein the plurality of bond pads is formed adjacent the first active at corresponding bottoms of the openings.

14. The method of claim 13, further comprising bonding a wire to each of the plurality of bond pads, wherein the wire extends through the opening.

15. The method of claim 12, wherein the plurality of bond pads is formed over the gapfill material, and electrically coupled to conductors at the first active surface by through-oxide vias.

16. The method of claim 15, further comprising forming the through-oxide vias by plating a conductor into the openings.

17. The method of claim 11, further comprising forming a metallization layer over the plurality of chiplets and the gapfill material, the metallization layer including conductive structures operably coupled to the plurality of chiplets through back-side contacts of the plurality of chiplets.

18. The method of claim 17, wherein the plurality of bond pads is formed over the metallization layer and in contact with corresponding ones of the conductive structures.

19. The method of claim 11, wherein hybrid-bonding the plurality of chiplets to the first active surface of the semiconductor wafer comprising forming, for each of the plurality of chiplets, dielectric-dielectric bonds between the second active surface and the first active surface, and metal-metal bonds between first interconnect structures at the first active surface and second interconnect structures at the second active surface.

20. The method of claim 11, wherein the gapfill material comprises silicon oxide.
